(19) United States
(12) Patent Application Publication
(10) Pub. No.: US 2025/0349566 A1
(43) Pub. Date: Nov. 13, 2025

(54) HEAT TREATMENT APPARATUS AND HEAT TREATMENT METHOD

(71) Applicant: TOKYO ELECTRON LIMITED, Tokyo (JP)

(72) Inventors: Katsuhiro IKEDA, Kumamoto (JP); Kazuhiko OOSHIMA, Kumamoto (JP); Hibiki OTANI, Kumamoto (JP); Kenji IIZUKA, Kumamoto (JP); Senri SUEMATSU, Kumamoto (JP); Kazunori SAKAMOTO, Kumamoto (JP); Kazuyuki IWAO, Kumamoto (JP); Hideto NOUDUKA, Kumamoto (JP); Shinichiro YAMANAKA, Kumamoto (JP)

(21) Appl. No.: 19/201,423

(22) Filed: May 7, 2025

(30) Foreign Application Priority Data
May 10, 2024 (JP) 2024-076956

(51) Int. Cl. H01L 21/67; H01L 21/02

(52) U.S. Cl. CPC H01L 21/67103; H01L 21/02118; H01L 21/02282; H01L 21/02318

(57) ABSTRACT

A heat treatment apparatus, includes: a stage configured to place a substrate on the stage before a film formed on the substrate is solidified; and a heater configured to heat the substrate placed on the stage to a temperature lower than a boiling point of a solvent included in the film.

### CROSS-REFERENCE TO RELATED APPLICATION

This application is based upon and claims the benefit of priority from Japanese Patent Application No. 2024-076956, filed on May 10, 2024, the entire contents of which are incorporated herein by reference.

### TECHNICAL FIELD

The present disclosure relates to a heat treatment apparatus and a heat treatment method.

### BACKGROUND

When manufacturing a semiconductor device, a film is formed by supplying a liquid to a semiconductor wafer (hereinafter, referred to as a wafer) which is a substrate, and the wafer is heated so as to remove a solvent in the film. Patent Document 1 describes that in heating the wafer, heating is performed stepwise at different temperatures.

### PRIOR ART DOCUMENTS

### Patent Documents

Patent Document 1: Japanese Patent Laid-Open Publication No. 2000-91218

### SUMMARY

According to one embodiment of the present disclosure, there is provided a heat treatment apparatus, including: a stage configured to place a substrate on the stage before a film formed on the substrate is solidified; and a heater configured to heat the substrate placed on the stage to a temperature lower than a boiling point of a solvent included in the film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a wafer processing system including a heat treatment apparatus of the present disclosure.

FIG. 2 is a front view of the wafer processing system.

FIG. 3 is a flowchart of processing of the wafer processing system.

FIG. 4 is a longitudinal side view of the heat treatment apparatus.

FIG. 5 is a partial cross-sectional plan view of a processing container in the heat treatment apparatus.

FIG. 6 is a longitudinal side view of the processing container.

FIG. 7 is a flowchart of processing of the heat treatment apparatus.

FIG. 8 is an explanatory view illustrating an operation of the heat treatment apparatus.

FIG. 9 is an explanatory view illustrating an operation of the heat treatment apparatus.

FIG. 10 is an explanatory view illustrating an operation of the heat treatment apparatus.

FIG. 11 is an explanatory view illustrating an operation of the heat treatment apparatus.

FIG. 12 is a schematic view illustrating a state of a wafer processed in the heat treatment apparatus.

FIG. 13 is a schematic view illustrating a state of the wafer processed in the heat treatment apparatus.

FIG. 14 is a schematic view illustrating a state of the wafer processed in the heat treatment apparatus.

FIG. 15 is a schematic view illustrating a state of the wafer.

FIG. 16 is a schematic view illustrating a state of the wafer.

FIG. 17 is a longitudinal side view illustrating a heat treatment apparatus according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A wafer processing system as a substrate processing apparatus according to an embodiment is described below with reference to the drawings. In this specification, elements having substantially the same functional configuration are designated by like reference numerals, and duplicated description is omitted.

### <Wafer Processing System>

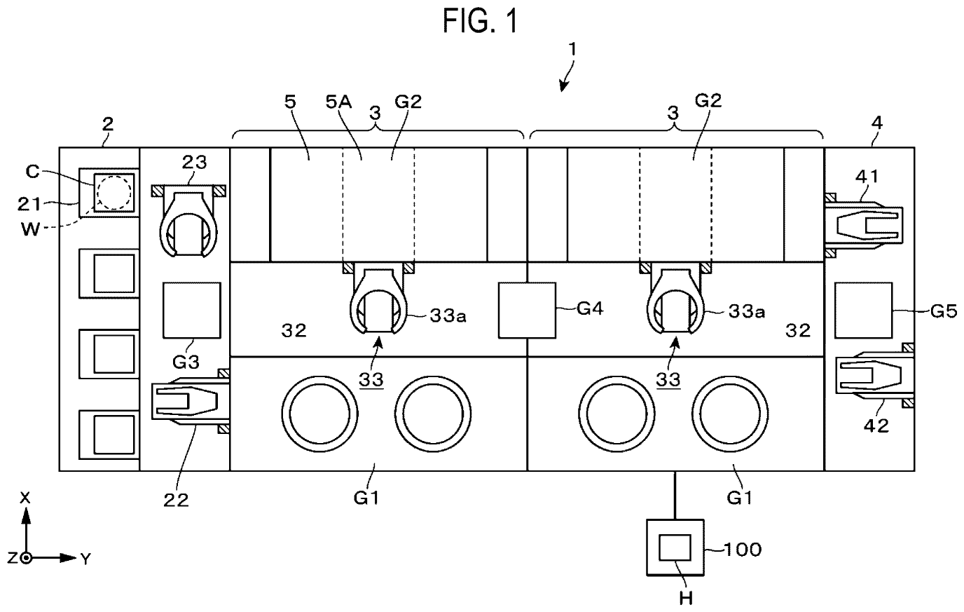

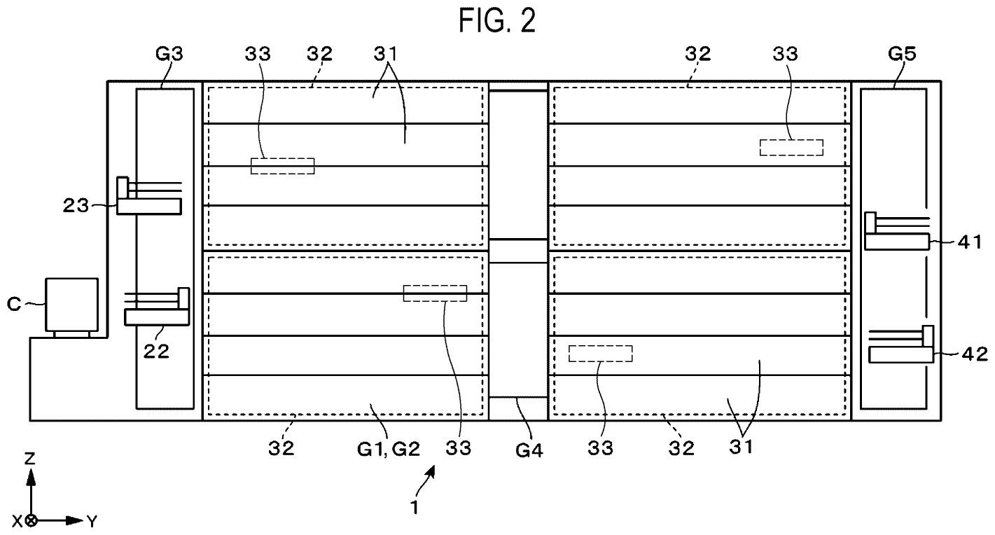

First, a configuration of a wafer processing system according to an embodiment is described. FIGS. 1 and 2 are respectively a plan view and a front view, which schematically illustrate an outline of a configuration of a wafer processing system 1. In this embodiment, a case where the wafer processing system 1 is a photolithography processing system that performs forming and development processings of a resist film on a wafer W is described as an example.

The wafer processing system 1 includes, as illustrated in FIG. 1, a cassette station 2 into/from which a cassette C accommodating a plurality of wafers W is loaded/unloaded, and a processing station 3 including a plurality of various kinds of processing apparatuses that perform a predetermined processing on the wafer W. Further, the wafer processing system 1 has a configuration in which the cassette station 2 and an interface station 4 that transfers the wafer W between the processing station 3 and an exposure apparatus (not illustrated) adjacent to a side opposite to the processing station 3 are integrally connected together. Further, two processing stations 3 are installed between the cassette station 2 and the interface station 4 as illustrated in FIG. 1, but one or three or more processing stations may be installed.

The cassette station 2 is provided with a plurality of cassette placing plates 21 and wafer transfer mechanisms 22 and 23. In the cassette station 2, the wafer is transferred between the cassette C placed on the cassette placing plate 21 and the processing station 3 by the wafer transfer mechanism 22 or 23. Therefore, each of the wafer transfer mechanisms 22 and 23 is provided with a drive mechanism in a direction such as an X direction, a Y direction, a vertical direction, or around a vertical axis (in a 0 direction) as needed, and may be provided with drive mechanisms in all the directions.

At least one of the wafer transfer mechanisms 22 and 23 may transfer the cassette C and the wafer, and may perform a transfer operation of the wafer with the processing station 3. Further, the transfer operation of the wafer with the processing station 3 is, for example, that the wafer is transferred between the processing station 3 and a third block G3 provided with a transfer apparatus, to which a wafer transfer mechanism 33 in the processing station 3, which will be described later, is accessible. The third block G3 may be provided with a plurality of transfer apparatuses (not illustrated) arranged in the vertical direction.

Further, an inspection apparatus (not illustrated) that performs inspection on the wafer W may be provided at a position to which any one of the wafer transfer mechanisms 22 and 23 is accessible.

The processing station 3 is provided with a plurality of blocks, e.g., three, i.e., first, second, and fourth blocks G1, G2, and G4. Further, as illustrated in FIG. 2, a plurality of layers 31 including the first and second blocks G1 and G2 is stacked in the vertical direction. For example, the first block G1 is provided at a front side (a side in a negative direction of the X direction in FIG. 1) in the processing station 3, and the second block G2 is provided at a rear side (a side in a positive direction of the X direction in FIG. 1) in the processing station 3. The fourth block G4 is provided near the interface station 4 (a side in a positive direction of the Y direction in FIG. 1) in the processing station 3 or provided in a connection portion between the processing station 3 and another adjacent processing station 3. The fourth block G4 may be provided with a plurality of transfer apparatuses arranged in the vertical direction. Further, the above-described third block G3 may be provided in the processing station 3.

In the first block G1, a plurality of processing apparatuses, e.g., patterning film forming apparatuses or development processing apparatuses, which are not illustrated, is disposed. As the patterning film forming apparatuses, for example, an anti-reflection film forming apparatus may be included in addition to a resist film forming apparatus.

For example, the plurality of processing apparatuses is arranged in a horizontal direction. Further, the number, the arrangement or the type of the processing apparatuses may be arbitrarily selected.

In the patterning film forming apparatuses or the development processing apparatuses, for example, the film formation or the development processing is performed by supplying a predetermined processing liquid on the wafer W or by supplying a predetermined gas on the wafer W. Accordingly, in the patterning film forming apparatuses, the formation of a resist film used as a mask when forming a pattern of a film of a lower layer side or the formation of an anti-reflection layer or the like for efficiently performing a light irradiation processing, e.g., an exposure processing is performed. Further, in the development processing apparatuses, an uneven shape as the mask is formed by removing a portion of an exposed resist film.

For example, in the second block G2, heat treatment apparatuses (not illustrated) that perform a heat treatment such as heating or cooling of the wafer W are arranged side by side in the vertical direction and in the horizontal direction. Further, in the second block G2, hydrophobizing processing apparatuses that perform a hydrophobizing processing to improve adhesivity between a resist liquid and the wafer W and periphery exposure apparatuses that perform exposure on an outer peripheral portion of the wafer W, which are not illustrated, are provided side by side in the vertical direction (a Z direction in FIG. 2) and the horizontal direction. The number or the arrangement of the heat treatment apparatuses, the hydrophobizing processing apparatuses, and the periphery exposure apparatuses may also be arbitrarily selected.

In a region between the first block G1 and the second block G2 in a plan view as illustrated in FIG. 1, a wafer transfer region 32 is formed. In the wafer transfer region 32, for example, the wafer transfer mechanism 33 is disposed.

The wafer transfer mechanism 33 includes, for example, a transfer arm 33a that is movable in the Y direction, a front-rear direction, the θ direction, and the vertical direction. The wafer transfer mechanism 33 may move in the wafer transfer region 32 to transfer the wafer W to a predetermined apparatus in the first block G1, the second block G2, the third block G3, or the fourth block G4, which is located at a periphery thereof. When a plurality of processing stations 3 is provided as illustrated in FIG. 1, the wafer transfer mechanism 33 provided in the processing station 3 located near the interface station 4 may transfer the wafer W to a predetermined apparatus in a fifth block G5 to be described later in addition to the first, second, and fourth blocks G1, G2, and G4.

For example, a plurality of wafer transfer mechanisms 33 is disposed vertically as illustrated in FIG. 2. One wafer transfer mechanism 33 may transfer the wafer W to a predetermined apparatus located in a height of an upper portion of the plurality of layers 31 among the plurality of layers 31 stacked vertically. Another wafer transfer mechanism 33 may transfer the wafer W to a predetermined apparatus located in a height of the plurality of layers 31 located below the upper portion of the plurality of layers 31. A plurality of wafer transfer regions 32 is provided to enables transfer of the wafer W. Further, the number of wafer transfer mechanisms 33 or the number of layers 31 corresponding to one wafer transfer mechanism 33 may be arbitrarily selected, such as that the wafer transfer mechanism 33 is provided for each one layer 31.

In addition, a shuttle transfer mechanism (not illustrated) may be provided in the wafer transfer region 32 or the first or second block G1 or G2. The shuttle transfer mechanism transfers the wafer W linearly between a space adjacent to one side of the processing station 3 and another space adjacent to a side opposite to the one side.

The interface station 4 is provided with the fifth block G5 including a plurality of transfer apparatuses and wafer transfer mechanisms 41 and 42. The interface station 4 transfers the wafer W between the fifth block G5 in which the wafer W is transferred by the wafer transfer mechanism 33 and an exposure apparatus by using the wafer transfer mechanism 41 or 42. Therefore, each of the wafer transfer mechanisms 41 and 42 is provided with a drive mechanism in a direction such as the X direction, the Y direction, the vertical direction, or around the vertical axis (in the θ direction) as needed, and may be provided with drive mechanisms in all the directions. At least one of the wafer transfer mechanisms 41 and 42 may support the wafer W and transfer the wafer W between the transfer apparatus in the fifth block G5 and the exposure apparatus.

A cleaning processing apparatus that cleans a surface of the wafer W or the above-described periphery exposure apparatus may be provided at a position to which any wafer transfer mechanisms 41 or 42 is accessible, within the interface station 4.

The inspection apparatus may be provided in the cassette station 2 as described above. However, even in the processing station 3 and the interface station 4, the inspection apparatus may be provided at a position to which any wafer transfer mechanism 33, 41 or 42 in FIG. 1 or 2 is accessible, within each of the processing station 3 and the interface station 4.

The above wafer processing system 1 is provided with a controller 100. The controller 100 is, for example, a computer, and has a program storage (not illustrated). In the program storage, a program for controlling a processing of the wafer W in the wafer processing system 1 is stored. Further, in the program storage, a program for controlling an operation of a drive system such as the above-described various kinds of processing apparatuses or transfer mechanisms to implement a wafer processing in the wafer processing system 1 is also stored. A step group is incorporated in each program so as to perform transfer and processing of the wafer W by controlling an operation of each part of the wafer processing system 1 as described above. The controller 100 is provided with one or more control circuits, and controls each operation of the step group by transmitting a control signal to each part of the wafer processing system 1 to execute the operation. Further, the program is recorded in a non-transitory recording medium H readable by the computer, and may be installed in the controller 100 from the recording medium H.

### <Operation of Wafer Processing System>

The wafer processing system 1 is configured as described above. Next, an example of a wafer processing performed using the wafer processing system 1 configured as described above is described.

First, the cassette C accommodating a plurality of wafers W is loaded into the cassette station 2 of the wafer processing system 1 and placed on the cassette placing plate 21. Subsequently, the wafers W in the cassette C are sequentially taken out by the wafer transfer mechanism 22 or 23 to be transferred to the transfer apparatus of the third block G3.

The wafer W transferred to the transfer apparatus of the third block G3 is supported by the wafer transfer mechanism 33 and transferred to the hydrophobizing processing apparatus provided in the second block G2 such that a hydrophobizing processing is performed on the wafer W. Subsequently, the wafer W is transferred to the resist film forming apparatus by the wafer transfer mechanism 33 such that a resist film is formed on the wafer W. After that, the wafer W is transferred to the heat treatment apparatus to be pre-bake-processed, and then transferred to the transfer apparatus of the fifth block G5. Further, when a plurality of processing stations 3 is provided as illustrated in FIGS. 1 and 2, the wafer W is first placed on the transfer apparatus of the fourth block G4 before transferred to the transfer apparatus of the fifth block G5, and then transfer of the wafer W between a plurality of wafer transfer mechanisms 33 is made. Further, the wafer W may be transferred to the periphery exposure apparatus by the wafer transfer mechanism 33 as needed such that an exposure processing on a peripheral edge of the wafer may be performed.

The wafer W transferred to the transfer apparatus of the fifth block G5 is transferred to the exposure apparatus by the wafer transfer mechanisms 41 and 42 to be exposure-processed as a predetermined pattern. Further, the wafer W may be cleaned in the cleaning processing apparatus before exposure-processed.

The exposure-processed wafer W is transferred to the transfer apparatus of the fifth block G5 by the wafer transfer mechanisms 41 and 42. After that, the wafer W is transferred to the heat treatment apparatus by the wafer transfer mechanism 33 to be exposed and bake-processed.

The exposed and bake-processed wafer W is transferred to the development processing apparatus by the wafer transfer mechanism 33 to be developed. After the development is ended, the wafer W is transferred to the heat treatment apparatus by the wafer transfer mechanism 33 to be post-bake-processed.

After that, the wafer W is transferred to the transfer apparatus of the third block G3 by the wafer transfer mechanism 33, and then transferred to the cassette C of a predetermined cassette placing plate 21 by the wafer transfer mechanism 22 or 23 of the cassette station 2. Accordingly, a series of photolithography processes is ended. An unnecessary one among ones exemplified as the processing apparatuses may not be provided, or a processing may not be performed in the unnecessary processing apparatus.

### <Descriptions of Forming Resist Film and Subsequent Heating>

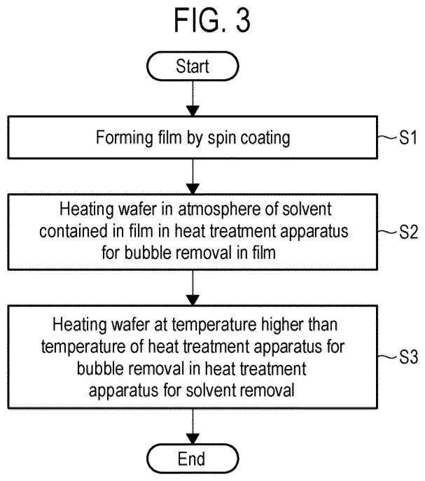

Forming a resist film and a subsequent heat treatment are described with reference to a flowchart of FIG. 3. The above-described forming of the resist film is performed in the resist film forming apparatus by supplying a resist (resist liquid), which is a liquid, to a central portion of the surface of the wafer W from a nozzle. Specifically, the forming of the resist film is performed by spin coating in which the resist is diffused to a peripheral edge of the wafer W by rotation of a stage that attracts and hold the wafer W (step S1). The resist is, for example, a resist including a wavelength of 365 nm as a photosensitive wavelength called an i-ray resist. Further, a viscosity of the resist is, for example, 50 cP to 10,000 cP before supplying the wafer W.

After forming the resist film, the wafer W is transferred to the heat treatment apparatus to be heated as described above. More specifically, the wafer W is first transferred to a heat treatment apparatus 5. At this time, since a solvent constituting a liquid resist remains in the resist film, the resist film is not solidified. Then, in the heat treatment apparatus 5, the wafer W is heated to a temperature lower than a boiling point of the solvent while forming a vapor atmosphere of the solvent released from the resist film (hereinafter, referred to as a solvent atmosphere) in a processing container 6 that accommodates the wafer W (step S2). As such, the wafer W is heated in the solvent atmosphere, so that foams (bubbles) contained in the resist film are removed as will be described in detail later.

After that, the wafer W is transferred to a heat treatment apparatus 5A different from the heat treatment apparatus 5. In the heat treatment apparatus 5A, the wafer W is heated to a temperature higher than a heating temperature of the wafer W in the heat treatment apparatus 5 such that the solvent remaining in the resist film is removed, and the resist film is solidified (step S3). Thus, so-called post apply bake (PA B) is performed in the heat treatment apparatus 5A. Further, the heating of the wafer W in the heat treatment apparatus 5 is performed before the resist film is solidified. The heat treatment apparatus 5A has, for example, the same structure as the heat treatment apparatus 5, which will be described later.

It is assumed that after the formation of the resist film, heating is performed at a relatively high temperature in the heat treatment apparatus 5A without performing heating in the heat treatment apparatus 5. In this case, the resist film is solidified in a state in which bubbles remaining in the resist film are expanded by heat to become relatively large bubbles, and hence there is a risk that subsequent pattern forming by photolithography or etching on the wafer W will not be normally performed. However, the processing by the heat treatment apparatus 5 prevents problems caused by bubbles remaining, as described above.

In addition, when the viscosity of the resist forming the resist film is relatively high as shown in the above-described range, ambient air is introduced to the resist to become bubbles when the resist is supplied by the nozzle or when the resist is diffused by the spin coating. After that, since fluidity of the resist is low, it is difficult the bubbles to be released to the outside of the film. That is, when forming a film by supplying a liquid having a viscosity in the above-described range and drying the liquid, bubbles are easily contained in the film, and hence it is particularly effective to perform a processing by the heat treatment apparatus 5.

### <Heat Treatment Apparatus for Bubble Removal>

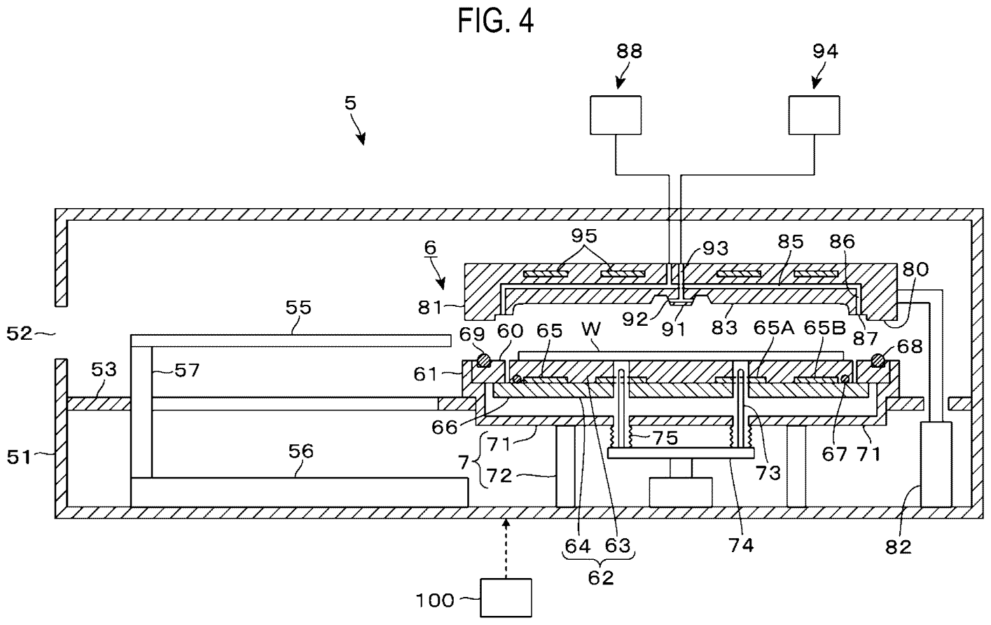

The heat treatment apparatus 5 is described below with reference to FIG. 4 which is a longitudinal side view. Reference numeral 51 in the drawing is a housing, and has a rectangular parallelepiped shape long in a front-rear direction. Reference numeral 52 is a transfer port of the wafer W, which is formed in a front wall of the housing 51. Reference numerals 53 is a separator, and is located below the transfer port 52 to vertically partition the interior of the housing 51.

In the housing 51, a transfer body 55 and the processing container 6 that accommodates and processes the wafer W are provided. The processing container 6 is located in a rear portion in the housing 51, and is provided with a lower structure 61 and a cover body 81. The cover body 81 is raised and lowered between a raised position and a lowered position by a lifting mechanism 82, so that the processing container 6 is opened and closed.

The lower structure 61 is provided with a heating plate 62 on which the wafer W is placed to be heated. The wafer transfer mechanism 33 described in FIG. 1 transfers the wafer W to the transfer body 55 located at a standby position (a position shown in FIG. 4) in a front portion in the housing 51. In a state in which the processing container 6 is opened, the transfer body 55 is movable forward and backward between the standby position and a transfer position above the heating plate 62, and the wafer W is transferred through pins to be described later between the transfer body 55 at the transfer position and the heating plate 62.

The transfer body 55 has a horizontal plate shape provided above the separator 53, and the wafer W is placed on an upper surface of the transfer body 55. The transfer body 55 is provided with a flow path of a fluid, which is not illustrated, and a temperature of the wafer W placed on the transfer body 55 is adjusted by heat exchanged with the fluid. A temperature of the fluid is set such that the wafer W, which is placed on the transfer body 55 after heated by the heating plate 62, is cooled. Reference numeral 56 is a transfer mechanism provided below the separator 53, and is connected to the transfer body 55 via a connector 57 to move the transfer body 55 forward and backward as described above.

### <Configuration of Processing Container>

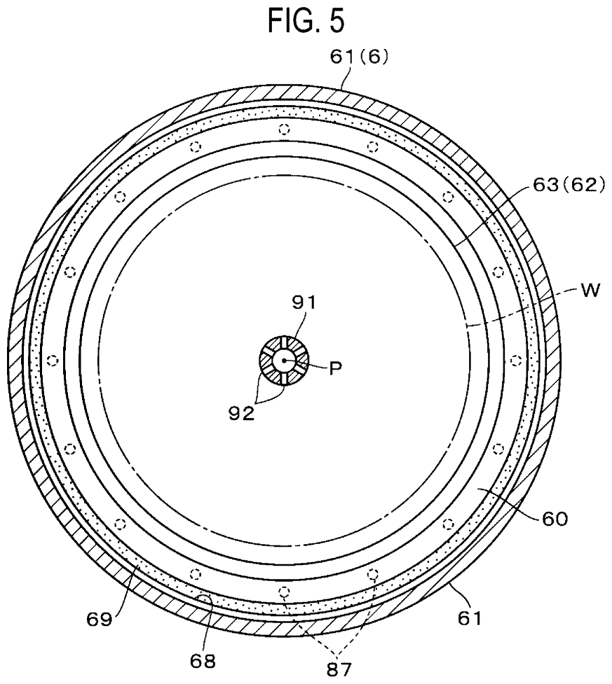

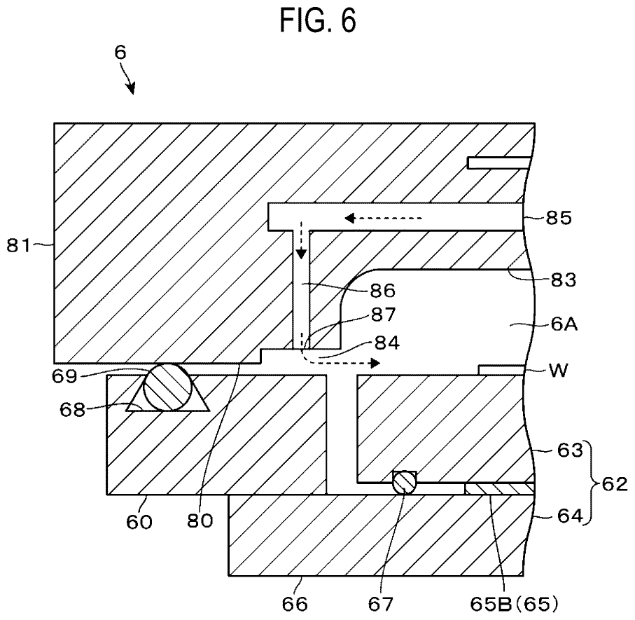

The processing container 6 is described below with reference to FIGS. 5 and 6 which are respectively a cross-sectional plan view and a partial longitudinal side view. FIG. 5 is a cross-sectional plan view of a protrusion 91 which will be described later, illustrates the heating plate 62 and the like, which are located below the protrusion 91, provides hatching and stippling respectively to the lower structure 61 and an O-ring 69, which will be described later, for the purpose of visibility, and shows a position of a gas supply port 87 to be described later, using a dotted line. Further, FIGS. 4 and 6 respectively show a state in which the cover body 81 is located at the raised position to be opened with respect to the processing container 6 and a state in which the cover body 81 is located at the lowered position to be closed with respect to the processing container 6, and an airtight space in the processing container 6, which is formed in the state in which the cover body 81 is closed, is defined as a processing space 6A. In the processing space 6A, a solvent atmosphere is formed as described above. Although will be described in detail later, when the solvent atmosphere is formed as described above, the processing container 6 is configured so that the vapor of the solvent does not leak to the outside and affect on a processing of the wafer W performed at a periphery of the heat treatment apparatus 5.

First, the lower structure 61 of the processing container 6 is described. The lower structure 61 includes the heating plate 62, a support ring 60, and a support body 7. The heating plate 62 constituting a stage of the wafer W includes an upper plate 63 and a lower plate 64, and is provided with a heater 65 as a heater (first heater). Each of the upper plate 63 and the lower plate 64 is, for example, a horizontal disk made of a metal, and the upper plate 63 is stacked on the lower plate 64 such that the upper plate 63 and the lower plate 64 are concentrically disposed with each other in a plan view. A diameter of the lower plate 64 is longer than a diameter of the upper plate 63. Therefore, the lower plate 64 protrudes from the upper plate 63 throughout the entire circumference of the upper plate 63, and a region of the lower plate 64 protruded from the upper plate 63 is defined as a flange portion 66. Further, a center of the upper plate 63 and the lower plate 64 in a plan view is represented as P in FIG. 5, and the wafer W is placed horizontally on the upper plate 63 such that a center of the wafer W is aligned with the center P.

The heater 65 is configured as, for example, a plate-shaped member including a conductive pattern as a heating element, and is interposed between the upper plate 63 and the lower plate 64 to heat the wafer W via the upper plate 63. The heater 65 includes a plurality of heaters 65, the plurality of heaters 65 is formed in shapes of circular rings having the center P as a center in a plan view, and diameters of the circular rings between the heaters 65 are different from each other. Hereinafter, for convenience, a heater provided near the center of the heating plate 62 may be described by reference numeral 65A, and a heater provided near a peripheral edge of the heating plate 62 may be described by reference numeral 65B. Further, reference numeral 67 in the drawings is an O-ring. The O-ring 67 is embedded in a groove formed in a lower surface of the upper plate 63 to surround the heaters 65A and 65B, and seals a gap between the upper plate 63 and the lower plate 64.

The heater 65B is configured such that a watt density (W/cm²), which is power per unit surface area, is increased as compared with the heater 65A. As will be described later, since a peripheral edge portion of the heating plate 62 comes in contact with the support ring 60, heat is transferred from the peripheral edge portion of the heating plate 62 to the support ring 60. In order to prevent a temperature of the peripheral edge portion of the heating plate 62 from being lower than a temperature of a central portion of the heating plate 62 due to the above-described heat transfer, the heater 65A and the heater 65B are designed to having different watt densities as described above.

Next, the support ring 60 is described. The support ring 60 is a circular ring member having the center P as a center in a plan view. The support ring 60 surrounds a side surface of the upper plate 63 throughout the entire circumference of the upper plate 63 to block heat toward the outside of the processing container 6 from the upper plate 63. The support ring 60 is made of, for example, resin. Since a gap is formed between the support ring 60 and upper plate 63, contact and interference of the upper plate 63 with the support ring 60 due to thermal expansion are prevented.

A lower surface of a central portion side of the support ring 60 is connected to the flange portion 66, and the heating plate 62 is supported by the support ring 60 through the above-described connection. The support ring 60 and the heating plate 62 are connected to each other as described above, so that an amount of heat transfer from the heating plate 62 to the support ring 60 becomes relatively large. Thus, the vapor of the solvent in the processing space 6A is prevented from remaining in the opening of the processing container 6 by being cooled and condensed on a surface of the support ring 60. That is, the solvent remaining as described above after the opening of the processing container 6 is evaporated, and it is possible to prevent the solvent from being leaked to the outside of the processing container 6.

An upper surface of the support ring 60 forms a horizontal surface, and has, for example, the same height as an upper surface of the upper plate 63 not to interrupt flow of a stream formed in the processing container 6 as will be described later. At a position in a vicinity of a peripheral edge portion of the upper surface of the support ring 60, a groove 68 is formed along a circumference of the support ring 60, and the O-ring 69 is embedded in the groove 68. The O-ring 69 is a seal member that adheres closely to a lower surface of the cover body 81 when the processing container 6 is closed, to make the processing space 6A sealed airtight.

As described above, heat of the heating plate 62 is transferred to the support ring 60 in contact with the heating plate 62. The heat is transferred to even the O-ring 69 in contact with the support ring 60. Therefore, a thermal expansion amount of the O-ring 69 becomes relatively large, so that adhesion to the cover body 81 is increased. Thus, since the airtightness of the processing space 6A is further increased, leakage of the solvent to the outside of the processing container 6 is more surely prevented.

The support body 7 is a member that supports the heating plate 62 and the support ring 60 on a bottom wall of the housing 51, and includes a support main body 71 and a support 72. The support main body 71 constitutes a bottom wall and a lower portion of a sidewall of the processing container 6, is provided to be embedded in an opening formed in the separator 53, and is supported from below by the support 72 provided on the bottom wall of the housing 51. The support main body 71 forms a recess in longitudinal cross-sectional view, and an upper portion of the recess is enlarged in a diameter to form an enlarged diameter portion. The support ring 60 is fitted into the enlarged diameter portion and connected to an inner peripheral surface of the support main body 71 to be supported by the support main body 71. Further, the heating plate 62 is spaced apart from the support main body 71.

In addition, three pins 73 that extend vertically and penetrate through the heating plate 62 and the support main body 71 are provided. Each pin 73 is connected to a lifting mechanism 74 below the support main body 71 and is capable of protruding and retracting on the heating plate 62 so as to perform transfer of the wafer W between the heating plate 62 and the transfer body 55, which is described above. Reference numeral 75 in the drawing is a bellows that ensures airtightness of the processing container 6. The bellows 75 surrounds the pins 73 and connects the lifting mechanism 74 and the support main body 71.

Next, the cover body 81 is described. The cover body 81 is configured in a horizontal disk shape. In the lower surface of the cover body 81, a circular recess 83 that forms the processing space 6A when the cover body 81 is closed is provided to face the heating plate 62. A center of the recess 83 is located at the center P in a plan view. The recess 83 is formed as described above, so that the cover body 81 constitutes an upper wall and an upper portion of the sidewall of the processing container 6.

A lower side of the recess 83 is widened toward a peripheral edge portion of the cover body 81 to form a flat circular ring-shaped recess, the processing space 6A having a relatively small volume is formed by the thin recess 83, and air is supplied to the recess as will be described later. An outer peripheral edge portion of the circular ring-shaped recess overlaps the support ring 60 in a plan view, and is located closer to the center P than the O-ring 69. In the state in which the cover body 81 is located at the lowered position (the state in which the processing container 6 is closed), a flow path formed by the recess on the support ring 60 is defined as a side flow path 84. A region outer than the side flow path 84 in the lower surface of the cover body 81 is configured as a horizontal seal surface 80, and faces the O-ring 69. In the state in which the cover body 81 is located at the lowered position, the seal surface 80 adheres to the O-ring 69.

A gas diffusion space 85 that is circular in a plan view is formed inside the cover body 81. A plurality of gas flow paths 86 extending toward below from a peripheral edge portion of the gas diffusion space 85 is formed at intervals along a circumferential direction of the gas diffusion space 85. Further, a lower end of each gas flow path 86 is opened to the side flow path 84 as the gas supply port 87, and is located to face the support ring 60. Therefore, the gas supply port 87 is opened outside of the upper plate 63.

In addition, a gas supply 88 is connected to the cover body 81. The gas supply 88 includes, for example, a gas supply source, a supply path connected to the gas supply source, a valve interposed in the supply path, and the like, and perform supply and stop of gas, e.g., air to a central portion of the gas diffusion space 85. The air supplied to the gas diffusion space 85 from the gas supply 88 is supplied onto the support ring 60 from the gas supply port 87.

A central portion of the recess 83 of the cover body 81 is further recessed upward, and a central portion of the recessed portion protrudes downward to form a circular protrusion 91. A plurality of exhaust ports 92 is opened horizontally in a side surface of the protrusion 91, and the exhaust ports 92 are provided at intervals along a circumferential direction. Therefore, each exhaust port 92 is located closer to the central portion of the heating plate 62 than the gas supply port 87, and is opened toward the peripheral edge portion of the heating plate 62 in a plan view.

Each exhaust port 92 is connected to a flow path 93 that extends downward from an upper surface of the cover body 81 in the central portion of the cover body 81 to reach the protrusion 91. An exhauster 94 is connected to the flow path 93 of the cover body 81. For example, the exhauster 94 includes an exhaust path connected to an exhaust source and a valve interposed in the exhaust path, and may switch between exhaust and non-exhaust from the exhaust port 92 via the flow path 93.

In this example, operations of the gas supply 88 and the exhauster 94 are controlled such that the exhaust from the exhaust port 92 is performed together with the supply of the air from the gas supply port 87. As will be described in detail later, a period in which the gas supply and exhaust is performed and a period in which the gas supply and exhaust is not performed are set in each of opening and closing of the processing container 6. The flow of air in a state in which the processing container 6 is closed to form the processing space 6A is indicated by a dotted arrow in FIG. 6. The gas supply and exhaust in the closing of the processing container 6 is performed to remove the solvent atmosphere such that solvent vapor is not leaked to the outside when the processing container 6 is opened.

The air exhausted onto the support ring 60 from the gas supply port 87 located outside of the heating plate 62 in a plan view flows toward a center portion of the processing container 6 via the side flow path 84 located on the support ring 60 by an exhaust action from the exhaust port 92. Then, the air flows on the wafer W placed on the heating plate 62 from a peripheral edge portion toward a central portion of the wafer W, and is introduced into the exhaust port 92. The vapor of the solvent in the processing space 6A is removed along a stream of the air formed as described above. As described above, since the air flows toward the center portion from a peripheral portion of the processing container 6, leakage of the vapor of the solvent to the outside of the processing container 6 is more surely prevented.

In addition, a height of the gas flow path 86 is larger than a height of a gap, which is formed between the seal surface 80 of the cover body 81 and the support ring 60, and is closer to the center of the processing container 6 relative to the O-ring 69. Further, a space is formed by the recess 83 to have a height larger than a height of the side flow path 84 on a central portion of the processing container 6 with respect to the side flow path 84. That is, with respect to the air supplied from the gas supply port 87 to the side flow path 84, pressure leakage of a flow path toward the center of the processing container 6 becomes lower than pressure leakage of a flow path toward the outside of the processing container 6. Therefore, it is difficult for the air to flow toward the outside of the processing container 6, and in this regard, leakage of the vapor of the solvent to the outside of the processing container 6 is more surely prevented.

In addition, the exhaust port 92 is opened in a lateral direction toward the peripheral edge portion of the heating plate 62 in a plan view as described above. The exhaust port 92 may be configured to be opened downward. However, in this case, air supplied from each gas supply port 87 is gathered below the exhaust port 92, flow of the air gathered as described above is formed such that the air flows upward. That is, since air is locally concentrated above the resist film that is not solidified, there is a risk that the air will have influence on a film thickness of the resist film. In other words, the exhaust port 92 is opened toward the peripheral edge portion of the heating plate 62 as described above, so that it is possible to suppress the flow of the air from having influence on the film thickness of the resist film, which is preferable.

In addition, a heater 95 is provided inside the cover body 81. Like the heater 65 provided in the heating plate 62, the heater 95 includes a plurality of heaters 65, the plurality of heaters 95 is formed in a plate shape forming circular rings having the center P as a center in a plan view, and diameters of the circular rings between the heaters 95 are different from each other. By the heater 95, the cover body 81 is heated, for example, to have the same temperature as the heating plate 62, so that condensation of the vapor of the solvent on the cover body 81 is prevented. That is, when the processing container 6 is opened, the condensed solvent is prevented from being evaporated and leaked to the outside of the processing container 6.

### <Processing of Wafer by Heat Treatment Apparatus 5>

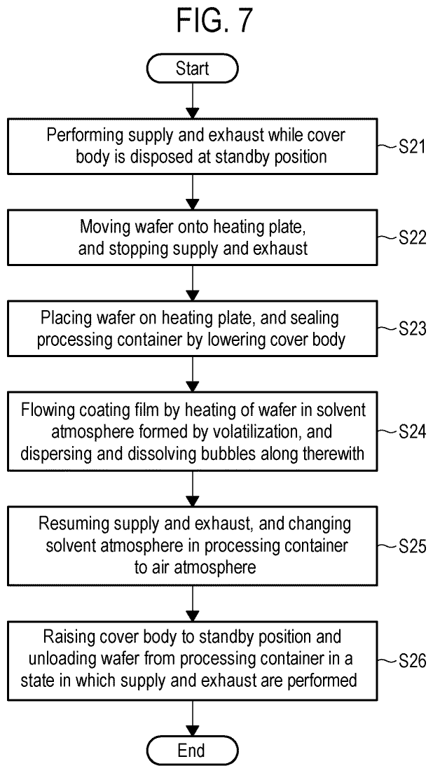

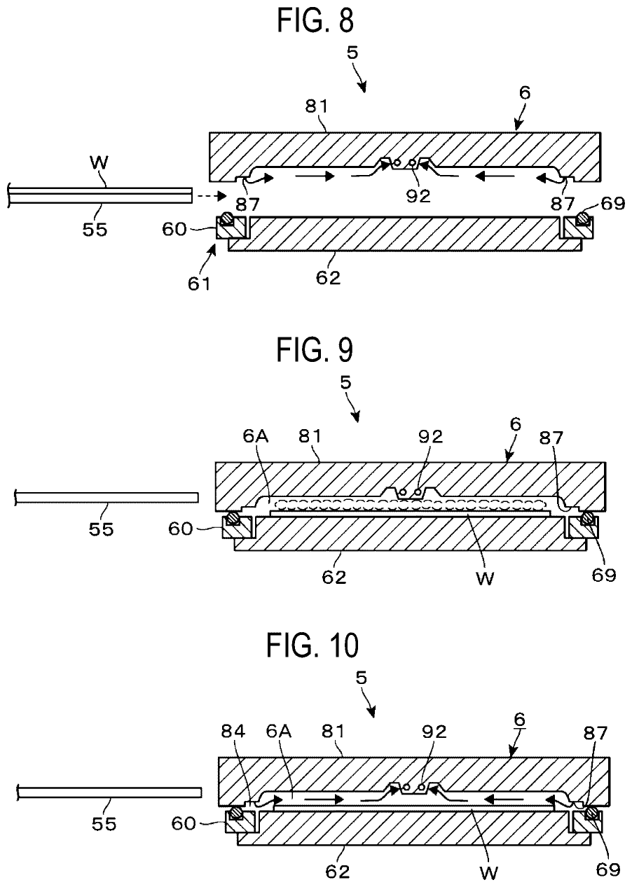

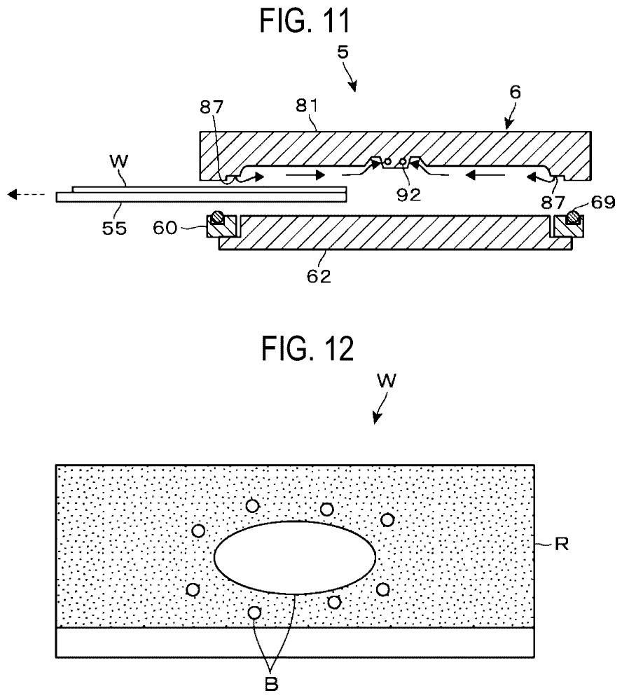

Next, a processing of a wafer W by the heat treatment apparatus 5 is described using a flowchart in FIG. 7, explanatory views illustrating operations of the heat treatment apparatus 5 in FIGS. 8 to 11, and schematic views illustrating states of a resist film R formed on the wafer W in FIGS. 12 to 14. It is assumed that before the processing of the wafer W, another wafer W is processed.

First, in the heat treatment apparatus 5 before the wafer W is loaded, the heating plate 62 is heated in advance to have a set temperature, and the set temperature in this example is constant, including a standby time for which no heat treatment is performed. The set temperature is a temperature lower than the boiling point of the solvent as described above, and is, for example, 50 degrees C. to 100 degrees C., more specifically, for example, 75 degrees C.

Then, the cover body 81 is disposed at the raised position which is a standby position, and the supply of air from the gas supply port 87 by the gas supply 88 and the exhaust from the exhaust port 92 by the exhauster 94 are performed (step S21, FIG. 8). That is, the processing container 6 is in a state in which the processing container 6 is opened. The air supplied from the gas supply port 87 flows along the lower surface of the cover body 81, is introduced into the exhaust port 92, and then flows toward the exhauster 94 to dry a flow path from the exhaust port 92 to the exhauster 94. The drying is described in detail later.

After that, when the transfer body 55 supporting the wafer W moves onto the heating plate 62, the pin 73 protrudes on the heating plate 62, so that the wafer W is supported by the pin 73. Meanwhile, the supply and exhaust by the gas supply 88 and the exhauster 94 are stopped (step S22). Subsequently, when the wafer W is placed on the heating plate 62 as withdrawal of the transfer body 55 from the heating plate 62 and lowering of the pin 73 are sequentially performed, the processing container 6 is sealed by moving the cover body 81 to the lowered position, so that the processing space 6A is formed (step S23). A time at which the wafer W is placed on the heating plate 62 is defined as time t1.

A solvent is gradually volatilized from a resist film of the wafer W heated by being placed on the heating plate 62. As time elapses, a solvent concentration of the processing space 6A is increased, and a solvent atmosphere is formed in the processing space 6A (FIG. 9). Further, in the processing space 6A having a relatively small volume, solvent vapor reaches a saturated state or a state close to the saturated state, so that the heating of the wafer W is continued in a state in which the solvent concentration is substantially constant. That is, vapor-liquid equilibrium is established between the solvent as liquid in the resist film and the solvent vapor in the processing space 6A, and fluidity of the resist film is maintained by the liquid solvent.

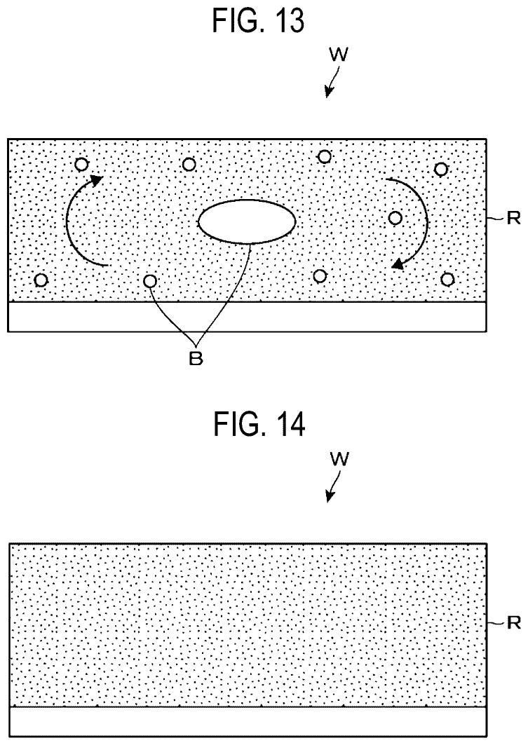

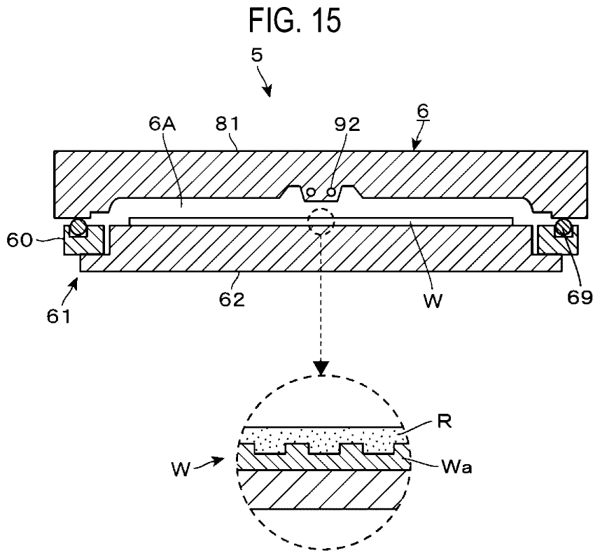

As illustrated in FIG. 12, various large and small bubbles B by air and the like, which are involved when coating a resist, are included in the resist film R. The wafer W is heated to a temperature lower than the boiling point of the solvent as described above, so that the solvent in the resist film R remains and flows on the wafer W without being excessively volatilized. Since mobility of the bubbles B is increased by the heating, the bubbles B is convected by the flow of the solvent to be diffused into the film. As a result that the bubbles B are finely broken or dissolved in the solvent in the film by movement in the film (FIG. 13), the bubbles B are removed from the resist film R (FIG. 14, step S24).

At time t2 after a predetermined time elapses from the time t1, by resuming the supply of the air from the gas supply port 87 and the exhaust from the exhaust port 92, the solvent vapor of the processing space 6A is exhausted to change the solvent atmosphere in the processing space 6A to an air atmosphere (step S25, FIG. 10).

When the solvent atmosphere in the processing space 6A is changed to the air atmosphere, the wafer W is unloaded from the heat treatment apparatus 5 in an inverse sequence to when loading the wafer W in a state in which the supply and the exhaust by the gas supply port 87 and the exhaust port 92 are continuously performed (step S26, FIG. 11). A time at which the wafer W is separated from the heating plate 62 by raising the pins 73 is defined as time t3. The supply and exhaust are continued even after unloading the wafer W, so that the above-described step S21 is re-performed. Although the solvent vapor sucked from the exhaust port 92 is condensed on a wall surface of the flow path from the exhaust port 92 to the exhauster 94 in the step S25, since the supply and exhaust are continued as described above, the solvent is evaporated and forced out to be removed from the flow path, thereby drying the flow path. Thus, leakage of the solvent to a periphery of the apparatus is more surely prevented.

The wafer W on which the bubbles B are dissolved and removed from the resist film R as described above is loaded into the heat treatment apparatus 5A to be placed on the heating plate 62 as described in FIG. 3, and, for example, is placed on the heating plate 62 in a state in which supply and exhaust in the processing container are performed, so that the solvent remaining in the film is removed. Since the bubbles are removed, occurrence of the above-described problem due to expansion of the bubbles is prevented. In addition, the heater 65 provided in the heating plate 62 of the heat treatment apparatus 5A corresponds to a second heater.

A period from the time t1 at which the wafer W is placed on the heating plate 62 to the time t3 is a heating period of the wafer W, and the heating period is, for example, 60 sec to 600 sec, more specifically, for example, 300 sec to 600 sec. During the heating period, a period (from the time t1 to the time t2) from start of the period to when the supply and exhaust of the processing space 6A are performed is defined as a first period, and a subsequent period (from the time t2 to the time t3) is defined as a second period. As described above, the first period is a period in which the bubbles are dissolved as the wafer W is heated in the solvent atmosphere. The first period is set relatively long such that the bubbles are surely removed. Specifically, the first period is set to, for example, a length equal to or longer than a half length of the heating period. Therefore, the second period is shorter than the first period, and is, for example, 30 sec.

In the processing example, in the first period, the exhaust by the exhauster 94 is not performed. However, as long as sufficient fluidity for removing the bubbles from the resist film may be ensured, the exhaust may be performed with a very small amount even in the first period. Therefore, an exhaust amount in the first period is set smaller than an exhaust amount in the second period, and the present disclosure is not limited to that the exhaust is not performed in the first period (i.e., the exhaust amount is 0). Further, both when the exhaust is performed in the first period and when the exhaust is not performed, the solvent atmosphere is formed in the processing space 6A by the above-described solvent vapor released from the wafer W to the processing space 6A. That is, this makes an operation of the exhauster 94 controlled such that a solvent concentration of the processing space 6A at a second time point after a first time point immediately after the processing space 6A is formed becomes higher than a solvent concentration of the processing space 6A at the first time point.

In this example, the supply by the gas supply 88 is performed together with the exhaust by the exhauster 94, but the supply by the gas supply 88 may not be performed. From the viewpoint of preventing the wafer W from moving due to inflow of gas from a periphery of the wafer W when opening the processing container 6 or more surely removing the solvent vapor in the processing container 6 by purging the solvent vapor, the supply is preferably performed.

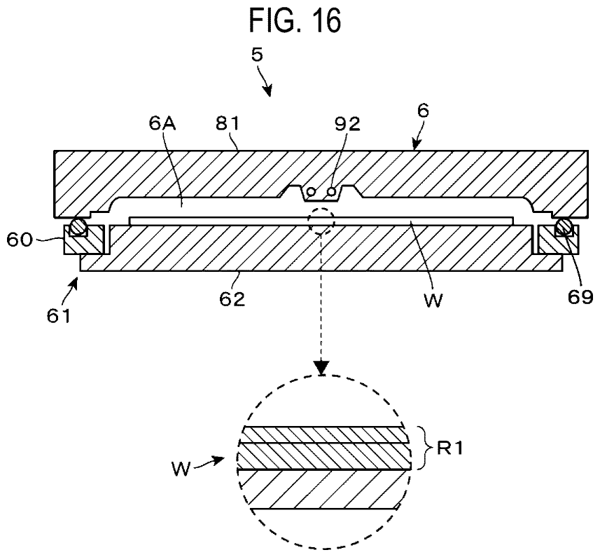

As described above, the heat treatment of the present disclosure is particularly useful for wafers W illustrated in FIGS. 15 and 16. In FIG. 15, a resist film R is formed to come in contact with steps pre-patterned in a surface layer Wa. That is, the resist film R is stacked and formed on a film forming an uneven pattern. When forming the resist film R, since air may be mixed when a resist is widely coated through spin coating and flows over the steps, there is a risk that a relatively many bubbles will be included in the resist film R. Therefore, it is valid to remove bubbles through heating by the heat treatment apparatus 5.

A Ithough the resist film as a coating film from which bubbles are to be removed has been described as an example, the present disclosure is not limited to the resist film. In the example shown in FIG. 16, a polyimide film R1 is a coating film from which bubbles are to be removed. More specifically, FIG. 16 shows an example in which the polyimide films R1 as the coating film are stacked and formed by repeatedly performing twice spin coating using a coating liquid including polyimide.

When performing the spin coating, for the purpose of improving wettability of a surface of the wafer W with respect to a coating liquid forming the coating film and improving extensibility by reduction in viscosity of the coating liquid before supplying the coating liquid onto the wafer W, a processing called pre-wet of supplying a solvent onto the surface of the wafer W in advance may be performed. However, when the polyimide film R1 is formed in a double-layer structure, the polyimide film R1 at a lower layer is melted if the pre-wet is performed when the polyimide film R1 at an upper layer is formed, and thus it is impossible to perform the pre-wet. Therefore, since a coating liquid for forming the polyimide film at the upper layer is diffused on the wafer W in a state in which viscosity of the coating liquid is relatively high, it is difficult for mixed bubbles to be discharged. Therefore, it is valid to remove the bubbles through heating by the heat treatment apparatus 5. Further, even when three or more films that are of the same kind are stacked, for the same reason, it is valid to remove the bubbles through heating by the heat treatment apparatus 5.

In addition, a test of examining removal performance of bubbles by the heat treatment apparatus 5, using the wafers W shown in FIGS. 15 and 16, was performed. Specifically, with respect to each wafer W, a number of bubbles in the film before the processing by the heat treatment apparatus 5 and a number of bubbles in the film after the processing by the heat treatment apparatus 5 were compared with each other. As a result, with respect to each wafer W, the number of bubbles after the processing was equal to or smaller than 1/10 of the number of bubbles before the processing. That is, a preferable effect that bubbles of 90% or more are removed was obtained.

### Modification

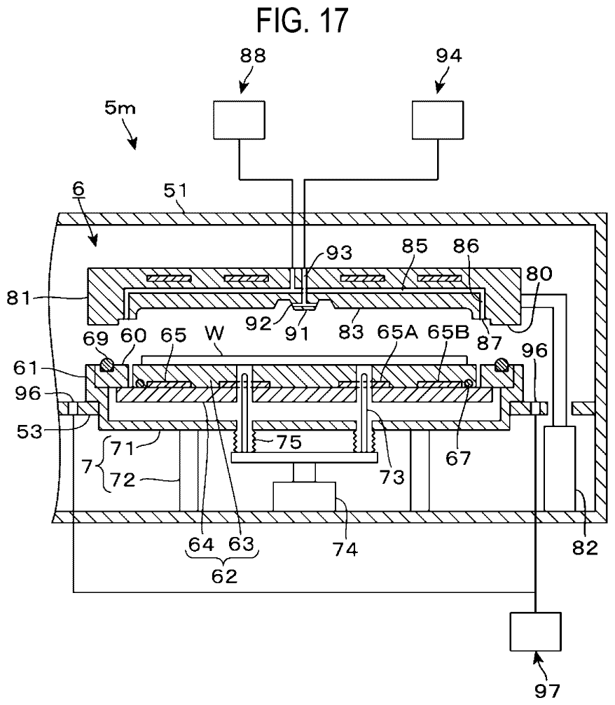

The above-described heat treatment for removing bubbles of the resist film according to the present disclosure is not limited to the heat treatment apparatus 5 having the structure, which has already been described. FIG. 17 is a partial longitudinal side view illustrating another heat treatment apparatus 5m for performing the heat treatment of the present disclosure. In the heat treatment apparatus 5m, an exhaust port 96 connected to an exhaust mechanism 97 is provided at an outside of the O-ring 69 that ensures airtightness of the processing container 6. The heat treatment apparatus 5m exhausts an atmosphere in the vicinity of the outside of the O-ring 69, so that it is possible to prevent solvent vapor from being diffused to the outside even when the solvent vapor is leaked from the processing container 6. The exhaust port 96 includes, for example, a plurality of exhaust ports 96 that is opened along a periphery of the pre-described opening of the separator 53 in which the lower structure 61 is disposed in the vicinity of the opening.

In addition, since the film to which the heat treatment of the present disclosure is applied may effectively remove bubbles considerably generated when formed by an i-ray resist, polyimide or the like, the heat treatment is preferably used for the resist film or the polyimide film, but may be applied to another resist film having a small number of bubbles, and the like. Further, the film is not limited to a case where the film is formed by spin coating, and may be applied to the film formed using a nozzle having a slit shape without rotating the wafer W.

In addition, in the heat treatment of the present disclosure, the wafer W is heated at a constant set temperature lower than the boiling point of the solvent. However, the present disclosure is not limited thereto, and the set temperature may be appropriately changed. Specifically, after a solvent atmosphere is formed by temporarily heating the wafer W at a temperature equal to or higher than the boiling point of the solvent and volatilizing the solvent, bubbles may be removed without solidifying the resist film by heating by the heating plate 62 weakly to a temperature less than the boiling point of the solvent. Further, in the heat treatment of the present disclosure, the wafer W is heated at a constant set temperature even when the atmosphere of the processing space 6A is changed to the air atmosphere by supply and exhaust, but the heating by the heater 65 may be weakened.

The heating plate is not limited to one in which the heater 65 as the heater is provided, and may have, for example, a configuration including a flow path through which a heated fluid flows. Further, the heating plate may have a device configuration in which the wafer W is heated by performing light irradiation by an LED as a heater from below with respect to the wafer W placed on a stage by which only a peripheral edge of a rear surface of the wafer W is supported. Therefore, the stage of the wafer W is not limited to the heating plate. Further, when performing heating by the LED as described above, a heating period of the wafer is a period in which light is irradiated onto the wafer W. The gas supply 88 supplies air, but may supply, for example, an inert gas.

In addition, the wafer processing system in the present disclosure is not limited to the above-described configurations and operations. A substrate processed in each wafer processing system is not limited to the wafer W, and may be a flat panel display (FPD) substrate or a mask substrate for manufacturing an exposure mask. While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

According to the present disclosure in some embodiments, it is possible to reduce a defect caused by bubbles when forming a film on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A heat treatment apparatus, comprising:
a stage configured to place a substrate on the stage before a film formed on the substrate is solidified; and
a heater configured to heat the substrate placed on the stage to a temperature lower than a boiling point of a solvent included in the film.

2. The heat treatment apparatus of claim 1, further comprising:
a processing container forming a processing space by surrounding the stage, configured to be closed during a heating period in which the substrate is heated by the heater, and including an exhaust port; and
an exhauster configured to exhaust the processing space from the exhaust port such that a concentration of the solvent in the processing space at a second time point in the heating period becomes higher than a concentration of the solvent in the processing space at a first time point in the heating period, the second time point being after the first time point.

3. The heat treatment apparatus of claim 1, wherein the film is formed by supplying, onto the substrate, a liquid that has a viscosity of 50 cP to 10,000 cP before being supplied onto the substrate, and includes an i-ray resist for exposure or polyimide.

4. The heat treatment apparatus of claim 3, wherein the film is formed to come in contact with a pattern having a step, which is formed in the substrate.

5. The heat treatment apparatus of claim 3, wherein the film is a stacked film in which a plurality of films of a same type overlap with each other.

6. The heat treatment apparatus of claim 1, wherein, when the heater is defined as a first heater, the substrate is transferred from the stage to a predetermined position and is heated in the predetermined position by a second heater for removing the solvent, and
wherein the first heater is configured to heat the substrate to a temperature lower than a heating temperature of the substrate by the second heater.

7. The heat treatment apparatus of claim 1, further comprising:
a processing container forming a processing space by surrounding the stage, configured to be closed during a heating period in which the substrate is heated by the heater, and including an exhaust port and a gas supply port;
an exhauster configured to exhaust the processing space from the exhaust port such that a first exhaust amount from the exhaust port in a first period in the heating period becomes smaller than a second exhaust amount from the exhaust port in a second period after the first period of the heating period, the first period being equal to or larger than a half of the heating period; and
a gas supply configured to supply a gas into the processing space from the gas supply port in the second period to change an atmosphere of the processing space from an atmosphere of the solvent to an atmosphere of the gas.

8. The heat treatment apparatus of claim 7, wherein the exhauster performs exhaust from the exhaust port in a period before the substrate is loaded into the processing container and a period including the second period.

9. The heat treatment apparatus of claim 7, wherein the stage is a heating plate including the heater,
wherein the gas supply port is opened outside the heating plate in a plan view, and
wherein the exhaust port is located closer to a central portion of the heating plate than the gas supply port and is opened toward a peripheral edge portion of the heating plate in the plan view.

10. The heat treatment apparatus of claim 9, wherein a support ring, which surrounds the heating plate and is connected to the heating plate, is provided at a position facing the gas supply port.

11. A heat treatment method, comprising:
placing a substrate on a stage before a film formed on the substrate is solidified; and
heating, by a heater, the substrate placed on the stage to a temperature lower than a boiling point of a solvent included in the film.

12. The heat treatment method of claim 11, further comprising:
closing a processing container surrounding the stage during a heating period in which the substrate is heated by the heater; and
exhausting, by an exhauster, a processing space from an exhaust port such that a concentration of the solvent in the processing space at a second time point in the heating period becomes higher than a concentration of the solvent in the processing space at a first time point in the heating period, the second time point being after a first time point.

13. The heat treatment method of claim 11, further comprising:
forming the film by supplying, onto the substrate, a liquid that has a viscosity of 50 cP to 10,000 cP before being supplied onto the substrate, and includes an i-ray resist for exposure or polyimide.

14. The heat treatment method of claim 13, further comprising:
forming the film to come in contact with a pattern having a step, which is formed in the substrate, by supplying the liquid onto the substrate.

15. The heat treatment method of claim 13, wherein the film is a stacked film, the heat treatment method further comprising:
forming the stacked film by overlapping a plurality of films of a same type.

16. The heat treatment method of claim 11, when the heater is defined as a first heater, further comprising:
transferring the substrate from the stage to a predetermined position; and
heating the substrate in the predetermined position by a second heater for removing the solvent,
wherein the heating the substrate by the first heater includes heating the substrate to a temperature lower than a heating temperature of the substrate by the second heater.

17. The heat treatment method of claim 11, further comprising:
closing a processing container surrounding the stage during a heating period in which the substrate is heated by the heater;
exhausting, by an exhauster, a processing space from an exhaust port such that a first exhaust amount from the exhaust port in a first period in the heating period becomes smaller than a second exhaust amount from the exhaust port in a second period after the first period of the heating period, the first period being equal to or larger than a half of the heating period; and
supplying, by a gas supply, a gas into the processing space from a gas supply port in the second period to change an atmosphere of the processing space from an atmosphere of the solvent to an atmosphere of the gas.

18. The heat treatment method of claim 17, wherein the exhausting of the processing space includes performing, by the exhauster, exhaust from the exhaust port in a period before the substrate is loaded into the processing container and a period including the second period.

19. The heat treatment method of claim 17, wherein the stage is a heating plate including the heater, and
wherein the changing of the atmosphere of the processing space includes:
supplying the gas from the gas supply port opened outside the heating plate in a plan view; and
performing exhaust from the exhaust port that is located closer to a central portion of the heating plate than the gas supply port and is opened toward a peripheral edge portion of the heating plate in the plan view.

20. The heat treatment method of claim 19, wherein the changing of the atmosphere of the processing space includes supplying the gas from the gas supply port toward a support ring provided at a position facing the gas supply port to surround the heating plate and be connected to the heating plate.
